(19) United States
(12) Patent Application Publication
(10) Pub. No.: US 2016/0173059 A1
(43) Pub. Date: Jun. 16, 2016

(54) Electrical Component Suitable For Miniaturization with Reduced Coupling

(71) Applicant: EPCOS AG, München (DE)

(72) Inventor: Edgar Schmidhammer, Stein an der Traun (DE)

(21) Appl. No.: 14/770,977

(22) PCT Filed: Jan. 28, 2014
(86) PCT No.: PCT/EP2014/051629

§ 371 Date: Aug. 27, 2015

(30) Foreign Application Priority Data
Mar. 6, 2013 (DE) 10 2013 102 210.3

(51) Int. Cl. H03H 9/10

(52) U.S. Cl. CPC H03H 9/10

(57) ABSTRACT

An electrical component includes a functional structure and a circuit element. In some embodiments, a chip is arranged between the functional structure and the circuit element thereby increasing the isolation between the functional structure and the circuit element. In some embodiments, the functional structure is arranged between the chip and a cover.

This patent application is a national phase filing under section 371 of PCT/EP2014/051629, filed Jan. 28, 2014, which claims the priority of German patent application 10 2013 102 210.3, filed Mar. 6, 2013, each of which is incorporated herein by reference in its entirety.

### TECHNICAL FIELD

The invention relates to electrical components which can be produced with small dimensions but nevertheless have low couplings between circuit elements.

### BACKGROUND

Electrical components, e.g., RF filters, which operate with acoustic waves or have MEMS component parts (MEMS=Micro-Electro-Mechanical System) are subject to a continuous trend toward miniaturization. In the case of electrical components constructed in an ever smaller fashion, couplings are problematic, e.g., electromagnetic couplings of different circuit elements, which reduce the signal quality.

What is problematic about electrical components having sensitive functional structures is that the structures have to be protected against harmful environmental influences, e.g., moisture in the atmosphere or dust. Components which operate with acoustic waves, e.g., SAW components (SAW=Surface Acoustic Wave), BAW components (BAW=Bulk Acoustic Wave) or GBAW components (GBAW=Guided Bulk Acoustic Wave), require functional structures in which the acoustic waves are capable of propagating without disturbance. Usually, therefore, such components require an encapsulated cavity in which the functional structure are arranged. Firstly, the corresponding encapsulations of the functional structures make the production of the components more expensive. Secondly, the encapsulations require additional space, which is at odds with miniaturization.

It is known to cover functional structures by lid wafers or by TFP (Thin-Film Package) covers. Electrical components having functional structures in which the cover does not significantly increase the lateral dimensions of the components are referred to as WLP (Wafer Level Packages).

What is problematic about such components is the spatial proximity of different circuit elements that is constrained by the miniaturization. In this regard, in the case of many electrical components of small construction, an undesirable situation, but one that cannot be prevented, is that electromagnetic couplings, e.g., between inductive elements and functional structures, impair the signal quality. Particularly functional structures in reception paths of mobile communication devices suffer excessively from miniaturization, and so electromagnetic coupling constitutes one of the most important obstacles to further miniaturization.

### SUMMARY

Embodiments of the invention specify an electrical component which is suitable for further miniaturization by virtue of a reduction of couplings.

An electrical component comprises an electrical circuit having a functional structure and a circuit element. The component furthermore comprises a chip. The chip is arranged between the functional structure and the circuit element. The isolation between the functional structure and the circuit element is increased by virtue of the chip being arranged therebetween and a coupling is therefore reduced.

Particularly the isolation between electromagnetically sensitive structures and impedance elements arranged on the other side of the chip is improved. The term electrical circuit can relate to any type of electrical interconnection of an electrical component. The functional structure can be a functional structure which operates with acoustic waves, e.g., an SAW, BAW or GBAW structure with an electroacoustic transducer. The chip can be a carrier chip for the functional structure and comprise, e.g., a piezoelectric material. The functional structure can then comprise structured electrode fingers on the piezoelectric material of the chip. The circuit element is then arranged on the other side of the chip as viewed from the functional structure. The material of the chip serves as a spatial spacer between the functional structure and the circuit element.

In one embodiment, the functional structure is arranged between the chip and a cover.

In this case, the arrangement can enable a hermetic encapsulation of the functional structure on the chip or comprise holes and allow the chip access to the surrounding atmosphere and at the same time protect the chip against mechanical damage as a result of relatively large particles.

In one embodiment, the cover is a thin-film cover such as, e.g., a TFP cover, a wafer level package cover, a lid chip, a plastic cap or a metal cap.

In this case, the cover can comprise different materials, e.g., electrical conductors or non-conductors, and different plastics or metals. The cover can in particular consist of a single layer or of a multiplicity of different layers. It is also possible to provide a plastic cover having a vapor-deposited metal layer for protecting the functional structure on the chip.

In one embodiment, the cover therefore has one or a plurality of layers. It is possible for the cover to have a planar top side.

The top side can thus be planarized, which is advantageous for the further processing of the component. In particular, the cover can have a planarization layer which in turn comprises SiO₂ (silicon dioxide) or Si₃N₄ (silicon nitride).

In one embodiment, the functional structure is selected from an SAW structure, a BAW structure, a GBAW structure or some other MEMS structure.

By way of example, MEMS capacitor switches comprising a dielectric material between a fixed electrode and a movable electrode or other mechanically movable structures are suitable as a possible MEMS structure.

In one embodiment, the circuit element is an inductive element, a capacitive element or a resistive element. Besides passive circuit elements, the circuit element can also be an active circuit element, e.g., a semiconductor switch.

The circuit element can be in particular an impedance element for the impedance matching of the electrical circuit of the component or an ESD protection element (ESD=Electrostatic discharge).

In one embodiment, the electrical circuit of the component comprises a direct interconnection of the functional structure with the circuit element, i.e., the functional structure is directly connected to the circuit element, wherein no further circuit element—apart from a signal line between the circuit element and the functional structure—is electrically conductively arranged between the two elements.

In one embodiment, the electrical circuit comprises a plated-through hole through the chip. The functional structure is interconnected with the circuit element by the plated-through hole.

Such a plated-through hole can be, e.g., a possibility for producing a direct interconnection between the functional structure and the circuit element. In this case, in particular, a so-called TSV (Through Silicon Via) can be provided as plated-through hole if the chip comprises silicon. The use of silicon chips and the processing of silicon chips are well known from the semiconductor industry and easily manageable. If the chip comprises a piezoelectric material, e.g., LiTaO₃ (lithium tantalate), LiNbO₃ (lithium niobate), quartz or some other piezoelectric material, it is possible to implement the plated-through hole as a TMV (TMV=Through Material Via). In one embodiment, the component furthermore comprises a further substrate, which is connected to the chip by means of an interconnection, e.g., a bump connection, and is interconnected with the interconnection of the component.

The bump connection used can be, in particular, pillar-shaped vertical connections, so-called pillars, which can comprise Ag (silver), Au (gold), SnAg (an alloy comprising tin and silver) or Cu (copper). One advantage of bump connections comprising copper pillars, besides the relatively high conductivity of copper, is the mechanical stability, which is improved, e.g., compared with SnAg pillars. Further circuit elements, e.g., active or passive circuit elements, can be arranged on or in the further substrate or at the underside of the further substrate. In particular, it is possible to arrange impedance matching elements, e.g., inductive, capacitive or resistive elements, in, on or below the substrate.

In one embodiment, the further substrate is a carrier substrate having a plurality of insulating layers composed of an insulating material. Impedance elements are structured in metallization planes between the insulating layers.

The further substrate can be in this case a ceramic multilayer substrate, e.g., composed of HTCC (High-Temperature Co-Fired Ceramics) or LTCC (Low-Temperature Co-Fired Ceramics). Other laminates as carrier substrate are likewise possible.

In this regard, it is possible to arrange further matching elements or ESD protection elements on, in or below the further substrate, thereby increasing the spatial distance between the functional structure on the top side of the chip and precisely these matching elements below the underside of the chip.

In one embodiment, the interconnection is at least one part of an RF circuit. In this regard, the functional structure can be at least one part of a filter which operates with acoustic waves, e.g., of a TX or RX filter. It is also possible for the functional structure to be a part of a duplexer which can be provided for being interconnected within a front-end circuit of a mobile communication device.

Such a component enables a duplexer of small construction having improved electrical properties since an impairment of the properties on account of electromagnetic coupling, in particular between inductive elements and a filter structure as functional structure, is eliminated or at least reduced. Particularly the spatial distance between inductive elements arranged in the component and BAW resonator surfaces comprising conductive layers, e.g., as electrode layers or as mirror layers, is increased without the lateral dimensions of the component overall being increased.

### BRIEF DESCRIPTION OF THE DRAWINGS

The invention is explained in greater detail below on the basis of exemplary embodiments and schematic figures, in which:

FIG. 1 shows an electrical component illustrating the basic concept of the present invention;

FIG. 2 shows an electrical component having a plated-through hole;

FIG. 3 shows an electrical component having a cover above the functional structure;

FIG. 4 shows a component having a lid-type cover;

FIG. 5 shows a component having a metallic cover;

FIG. 6 shows a component having plated-through holes and solder bumps;

FIG. 7 shows a component in which the cover comprises a further layer;

FIG. 8 shows a component having a plurality of functional structures below individual covers;

FIG. 9 shows a component having a further substrate as carrier substrate;

FIG. 10 shows a component having a multiplicity of individually covered functional structures with a common further layer as part of a common cover;

FIG. 11 shows a component having a common cover and a further substrate;

FIG. 12 shows a component having circuit elements at the underside of the chip and at the top side of a further substrate;

FIG. 13 shows a component having circuit elements arranged in the interior of a multilayer substrate; and

FIG. 14 shows a component having covered functional structures, having a common further layer as part of a common cover and further component parts on the common cover.

### DETAILED DESCRIPTION OF ILLUSTRATIVE EMBODIMENTS

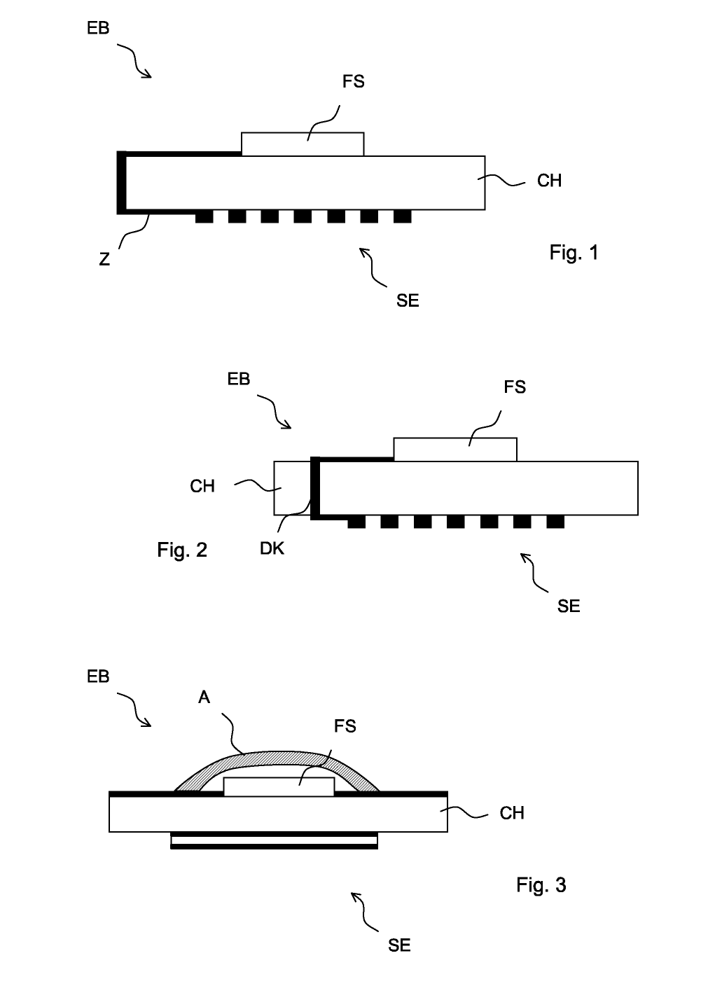

FIG. 1 shows an electrical component EB, in which a functional structure FS is arranged on the top side of a chip CH. A circuit element SE, here in the form of an inductive element embodied in coil form, is arranged on the underside of the chip and is interconnected with the functional structure FS on the top side of the chip CH by means of a lead as electrical signal line Z. The spatial separation of the circuit element SE from the functional structure FS by virtue of the arrangement of the chip CH therebetween increases the spatial distance and thereby reduces a possible coupling between the functional structure FS and the circuit element SE. In general, functional structures, e.g., structures operating with acoustic waves or MEMS structures, require a carrier substrate, e.g., a chip. Further circuit elements, here the circuit element SE, are necessary in order that the functional structure can operate properly. An electrical component EB therefore comprises the elements shown in FIG. 1 anyway. The electrical component EB is therefore not enlarged in terms of its lateral dimensions. By virtue of the arrangement of the chip CH between the functional structure FS and the circuit element SE, the coupling is reduced despite a small design.

FIG. 2 shows one embodiment of the component EB, wherein the circuit element SE and the functional structure FS are interconnected via a plated-through hole DK. A plated-through hole DK is generally better suited to the interconnection of the component parts of the circuit since the length of the lead Z is shortened in comparison with the lead in FIG. 1, in which it is led around the chip.

FIG. 3 shows one embodiment of the electrical component EB in which the functional structure FS is encapsulated by a cover A and is therefore isolated, e.g., hermetically, from the environment. In this case, the cover A can provide a cavity in which the functional structure is arranged without touching the walls of the cavity. If the functional structure operates, e.g., with acoustically active regions, then there is usually a desire for the acoustic energy not to leave the functional structure FS. The fact that the functional structure is not touched by the cover A therefore enables a good acoustic isolation of the functional structure FS. The further circuit element, here for example, in the form of a capacitive element having two conductive electrodes and a dielectric material therebetween, is arranged on the underside of the chip CH.

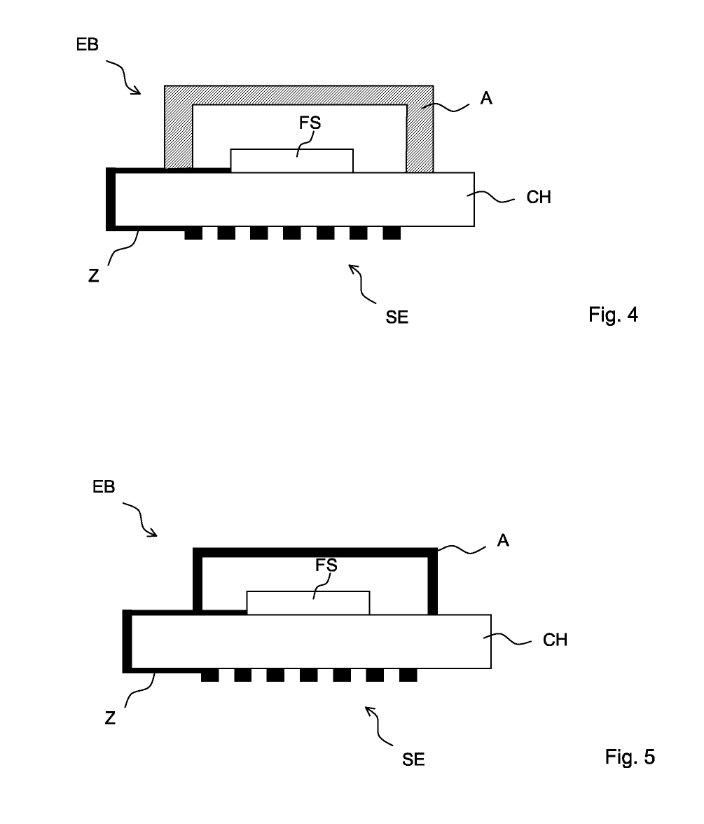

FIG. 4 shows one embodiment of the component EB in which the cover A is embodied by a lid, which can comprise a plastic material, e.g., a polymer, or which is embodied as a lid chip.

FIG. 5 shows one embodiment of the component EB in which the cover A is embodied by a lid comprising metal. A lid with metal enables a good electromagnetic shielding in particular against electric fields.

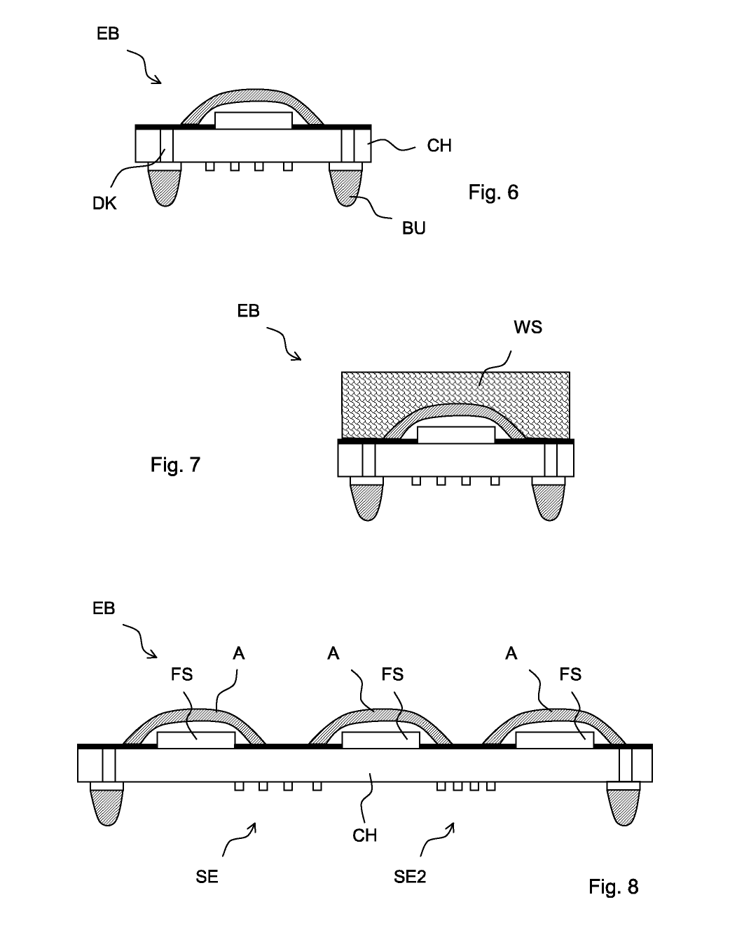

FIG. 6 shows one embodiment in which plated-through holes DK are led through the chip CH. The plated-through holes DK are connected to and interconnected with bump connections BU on the underside of the chip. The electrical component can be connected to and interconnected with a further substrate by means of the bump connections BU.

FIG. 7 shows an electrical component EB in which the cover comprises a further layer WS. In this case, the further layer WS can realize a mechanical reinforcement of the first cover layer, on which the further layer WS is arranged. Furthermore, the further layer WS can also constitute an improvement of the hermetic encapsulation and/or serve as a planarization layer. It is also possible for the further layer WS to be a molding layer composed of a molding material which is applied to the first layer of the cover in a liquid or viscous state and is subsequently cured.

FIG. 8 shows one embodiment in which a multiplicity, e.g., three, of functional structures are arranged on the top side of a chip. It is possible for each of the functional structures to be covered by a dedicated cover A. However, it is also possible for different functional structures to be arranged below a common cover A. A circuit element SE and a further, second circuit element SE2, here in the form of coil-type inductive elements, are arranged on the underside of the chip CH. It is advantageous if the further circuit elements SE are arranged on the underside of the chip at such locations above which no functional structure FS is situated directly. The circuit elements on the underside are then arranged “intermittently” relative to the functional structures, such that the electromagnetic coupling between circuit elements on the underside and functional structures FS on the top side of the chip is reduced further.

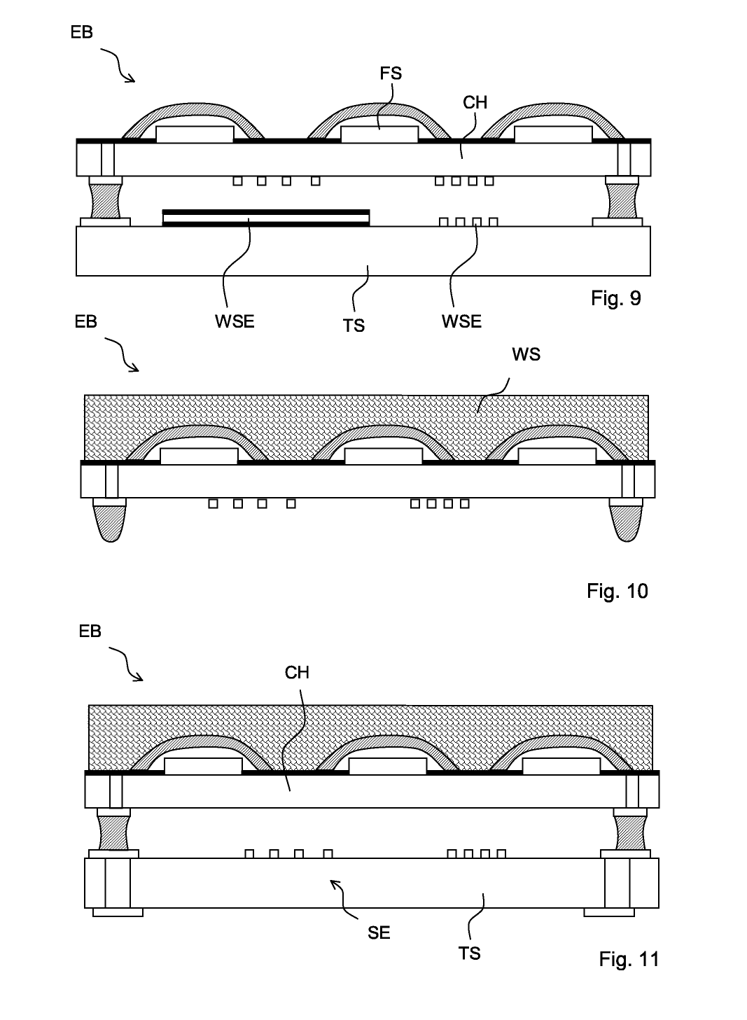

FIG. 9 shows one embodiment, wherein the chip CH with functional structures FS is arranged on a further substrate, a carrier substrate TS, and is interconnected with the carrier substrate TS. The carrier substrate TS can have further circuit elements WSE on its top side, i.e., on the side facing the chip CH, or on the underside, i.e., the side facing away from the chip. The further circuit elements can be impedance elements such as capacitive or inductive elements.

FIG. 10 shows one component EB in which a multiplicity of individual first cover layers are covered jointly by a further cover layer WS. The further layer WS can be used for producing a planar surface of the entire component and improve the mechanical stability and/or the hermetic and/or electromagnetic encapsulation of the functional structures.

FIG. 11 shows one component in which the circuit element SE is arranged not on the underside of the chip CH, but rather on the top side of a carrier substrate TS. Compared with embodiments with circuit elements SE directly at the underside of the chip CH, the spatial distance between the functional structure and the circuit element SE is increased further and the coupling is thereby reduced.

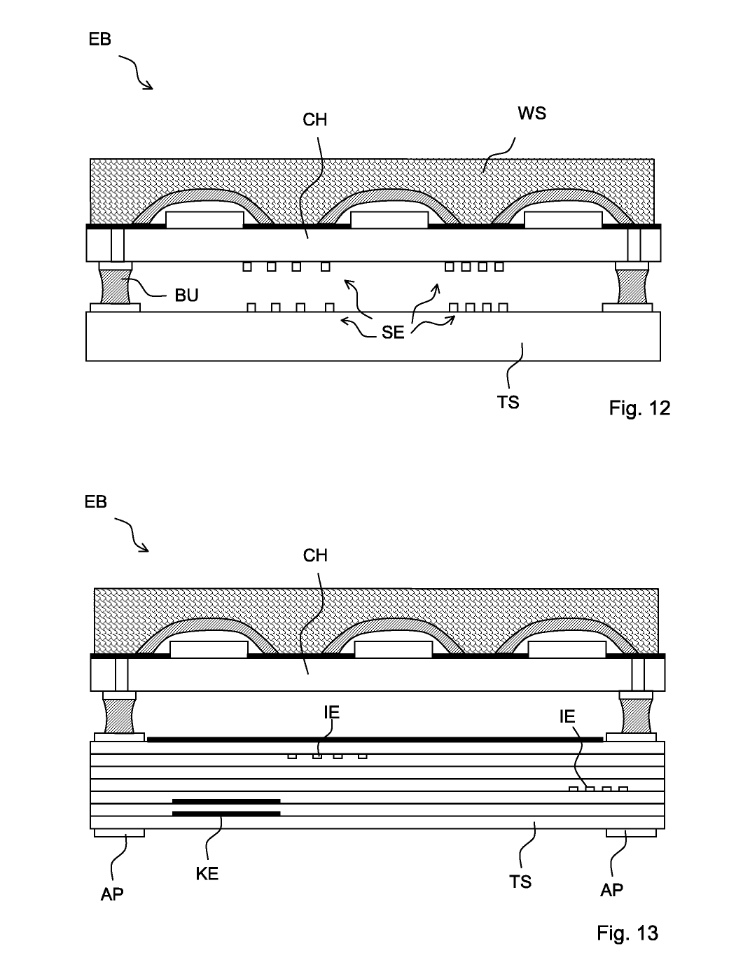

FIG. 12 shows one component EB in which circuit elements are arranged both on the underside of the chip CH and at the top side of the carrier substrate TS. At the same time, individual first cover layers are covered by a common further cover layer WS.

FIG. 13 shows one electrical component EB in which inductive elements IE and a capacitive element KE are arranged in metallization planes of a multilayer substrate as carrier substrate TS and interconnected with the circuit of the electrical component. Connection pads AP are arranged on the underside of the carrier substrate TS and are interconnected with the interconnection of the component, by means of which the component with its interconnection can be integrated in an external circuit environment.

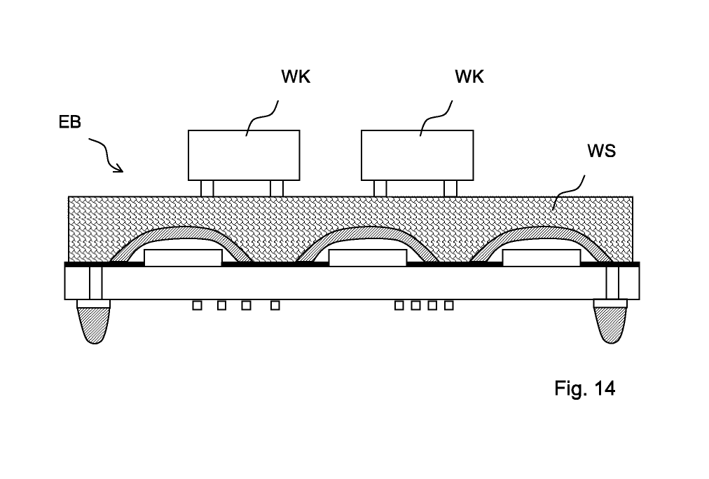

FIG. 14 shows one electrical component EB in which further component parts WK are arranged on the further layer WS and, if appropriate, are interconnected with circuits of the component. Each further component part WK can be an SMD component, a conductor structure, a capacitive or inductive circuit element, some other passive circuit element or an active circuit element. An interconnection with other circuit elements is possible via a line led over the edge (as depicted schematically in FIG. 1) or via a plated-through hole, e.g., a TMV, through the further layer WS.

The electrical component is not restricted to any of the embodiments shown. Further embodiments having additional circuit elements, additional layers of the cover and additional substrates or functional structures and combinations thereof likewise constitute exemplary embodiments according to the invention.

1-11. (canceled)

12. An electrical component, comprising:
an electrical circuit having a functional structure and a circuit element; and
a chip arranged between the functional structure and the circuit element, the chip increasing isolation between the functional structure and the circuit element.

13. The electrical component according to claim 12, further comprising a cover, wherein the functional structure is arranged between the chip and the cover.

14. The electrical component according to claim 13, wherein the cover comprises a thin-film cover, a WLP (wafer level package) cover, a lid chip, a plastic cap, or a metal cap.

15. The electrical component according to claim 14, wherein the cover has a plurality of layers and a planar top side.

16. The electrical component according to claim 14, wherein the cover has a single layer and a planar top side.

17. The electrical component according to claim 12, wherein the functional structure comprises a SAW structure, a BAW structure, a GBAW structure, or a MEMS structure.

18. The electrical component according to claim 12, wherein the circuit element comprises an inductive element, a capacitive element, or a resistive element.

19. The electrical component according to claim 12, wherein
the electrical circuit comprises a plated-through hole through the chip; and
the functional structure is electrically connected to the circuit element via the plated-through hole.

20. The electrical component according to claim 12, wherein the electrical circuit further comprises a direct interconnection between the functional structure and the circuit element.

21. The electrical component according to claim 20, further comprising a substrate connected to the chip by a bump connection, the substrate electrically connected to the interconnection.

22. The electrical component according to claim 21, wherein the substrate comprises a carrier substrate having a plurality of insulating layers composed of an insulating material and also comprises impedance elements structured in metallization planes between the insulating layers.

23. The electrical component according to claim 20, wherein the interconnection is at least one part of an RF circuit.

24. An electrical component, comprising:
a chip including a plated-through hole extending from a first main surface to an opposite second main surface of the chip, wherein the plated through-hole is part of an RF circuit;
a functional structure disposed on the first main surface of the chip, the functional structure comprising a SAW structure, a BAW structure, a GBAW structure, or a MEMS structure; and
a circuit element disposed on the second main surface of the chip and electrically connected to the functional structure by the plated-through hole, wherein the circuit element comprises an inductive element, a capacitive element, or a resistive element.

25. The electrical component according to claim 24, wherein the presence of the chip between the functional structure and the circuit element increases isolation between the functional structure and the circuit element.

26. The electrical component according to claim 24, further comprising a cover overlying the functional structure so that the functional structure is arranged between the chip and the cover.

27. The electrical component according to claim 26, wherein the cover comprises a thin-film cover, a wafer level package cover, a lid chip, a plastic cap, or a metal cap.

28. The electrical component according to claim 24, further comprising a substrate connected to the chip by a bump connection and electrically connected to the plated through-hole.

29. The electrical component according to claim 28, wherein the substrate comprises a carrier substrate having a plurality of insulating layers composed of an insulating material and also comprises impedance elements structured in metallization planes between the insulating layers.
